(19) United States
(12) Patent Application Publication
(10) Pub. No.: US 2026/0344390 A1
(43) Pub. Date: Oct. 29, 2026

(54) INTERCONNECT STRUCTURE FOR SEMICONDUCTOR DEVICE AND METHOD OF FORMING THE SAME

(71) Applicant: Taiwan Semiconductor Manufacturing Co., Ltd., Hsinchu (TW)

(72) Inventors: Wei-Chen Chu, Taichung City (TW); Chia-Tien Wu, Taichung City (TW); Chia Chen Lee, Taipei City (TW); Shu-Yun Ku, Hsinchu (TW)

(21) Appl. No.: 19/732,412

(22) Filed: Jul. 6, 2026

Related U.S. Application Data
(63) Continuation of application No. 19/035,335, filed on Jan. 23, 2025.
(60) Provisional application No. 63/695,105, filed on Sep. 16, 2024.

(51) Int. Cl. H10W 20/00; H10D 84/01; H10D 84/85; H10P 50/28; H10W 20/41; H10W 20/42

(52) U.S. Cl. CPC H10W 20/082; H10D 84/0186; H10D 84/851; H10W 20/089; H10W 20/42; H10W 20/435; H10D 84/856; H10P 50/283; H10W 20/057

(57) ABSTRACT

In an embodiment, a method may include forming a via hole in a dielectric layer, performing a directional etching process to enlarge one side of the via hole, and after the directional etching process, forming a trench hole in the dielectric layer, where the trench hole is above and spatially connected with the via hole, where the directional etching creates an asymmetrical profile having a first side width and a second side width measured from a center of the via hole, the second side width being greater than the first side width. The method may further include filling the via hole and the trench hole with a conductive material.

### PRIORITY CLAIM AND CROSS-REFERENCE

This application is a continuation of U.S. patent application Ser. No. 19/035,335, filed Jan. 23, 2025, entitled “Interconnect Structure for Semiconductor Device and Method of Forming the Same,” which claims the benefit of the following provisionally filed U.S. Patent application: Application No. 63/695,105, filed on Sep. 16, 2024, and entitled “SINGLE DIRECTION VIA ELONGATION,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 7 are views of intermediate stages in the manufacturing of CFETs in accordance with some embodiments.

FIGS. 8A-12C illustrate a formation process of a portion of an interconnect structure with an asymmetrical conductive via using a dual damascene process in accordance with some embodiments.

FIGS. 13-17 illustrate a formation process of a portion of an interconnect structure with an asymmetrical conductive via using a single damascene process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the field of semiconductor manufacturing, as technology nodes continue to shrink, the challenges associated with via formation and contact resistance become increasingly relevant. Conventional via formation processes often result in limited contact area between the via and the overlying metal layer, especially as more advanced layout techniques remove portions of the metal layers to push for density and performance enhancement.

One particular challenge arises when a via is located on the sidewall of an overlying metallization layer or at the line-end of an underlying metallization layer. In these cases, the contact area between the via and the overlying metal layer is further reduced, which may increase contact resistance. Additionally, as manufacturers employ layout push techniques such as enclosure reduction or cut metallization layer removal to improve density and reduce costs, the issues associated with via formation may become more pronounced.

In some embodiments, cut metallization layer removal may refer to a layout optimization technique where portions of a metallization layer are selectively removed or not formed to enhance performance or density. This includes removing originally planned metallization segments to reduce parasitic capacitance, adjusting metal patterns to accommodate via placement, or modifying metal fill patterns to meet density requirements. In some embodiments, enclosure reduction may refer to decreasing the extent of overlap between a via structure and its corresponding metallization layer beyond minimum design rules, while maintaining electrical connectivity. This reduction may be employed to improve routing density or reduce capacitive loading.

To address these challenges, a new approach to via formation has been developed. This approach involves a single direction via elongation technique that can be applied to both dual damascene and single damascene processes, as well as to various via layers, including the via to source/drain layer. The process begins with the formation of a via hole in a dielectric layer. Then, a directional etching process is employed to enlarge one side of the via hole, creating an asymmetrical profile.

This asymmetrical via profile offers several advantages. First, it increases the contact area between the via and the overlying metal layer, which helps to reduce contact resistance. Second, it maintains the original bottom width of the via, which is crucial for preserving the time-dependent dielectric breakdown (TDDB) window between the via and adjacent portions of the underlying metal layer. This balance between increased contact area and maintained bottom width is key to improving performance while ensuring reliability.

Furthermore, the single direction via elongation technique improves the via contact window, providing greater tolerance for overlay variations. This increased process window can lead to improved manufacturing yield, especially in advanced technology nodes where precise alignment becomes increasingly challenging.

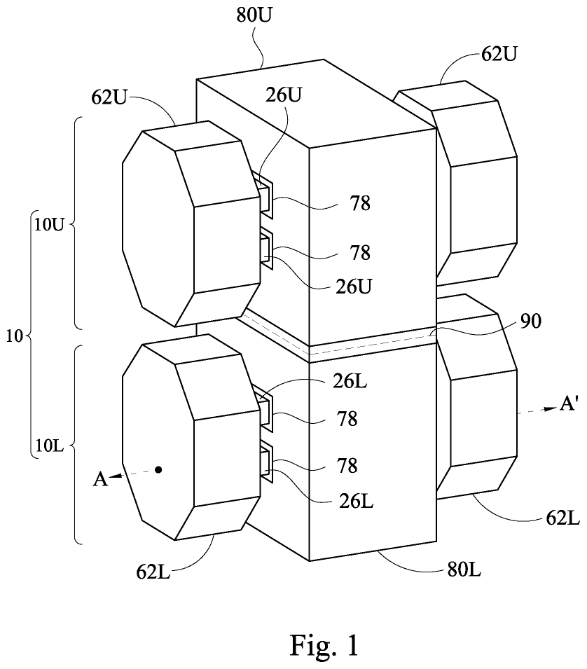

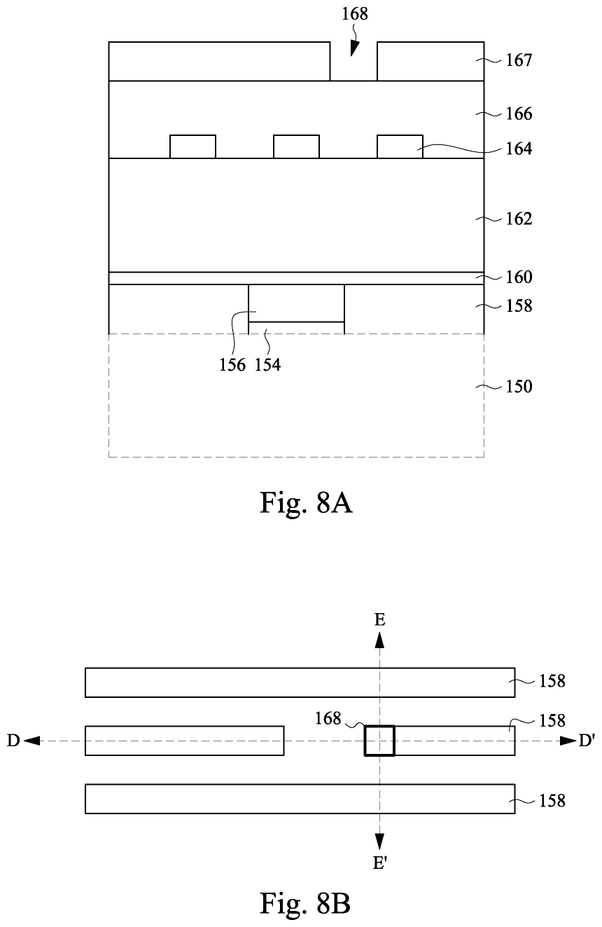

FIGS. 1 through 7 provide a description of forming a complementary field-effect transistor (CFET) structure. However, the disclosed interconnect structure and the asymmetrical via formation of FIGS. 8A-17 are not limited to CFETs, but may be utilized in other types of devices, such as a FinFET, a ferroelectric memory FET (FEMFET), or the like.

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the CFETs may be applied to other types of transistors (e.g., FinFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates a reference cross-section that is used in later figures. Cross-section A-A′ is a vertical cross-section that is parallel to a longitudinal axis of the semiconductor nanostructures 26 of a CFET and in a direction of, for example, a current flow between the source/drain regions 62 of the CFET. Subsequent figures may refer to this reference cross-section for clarity.

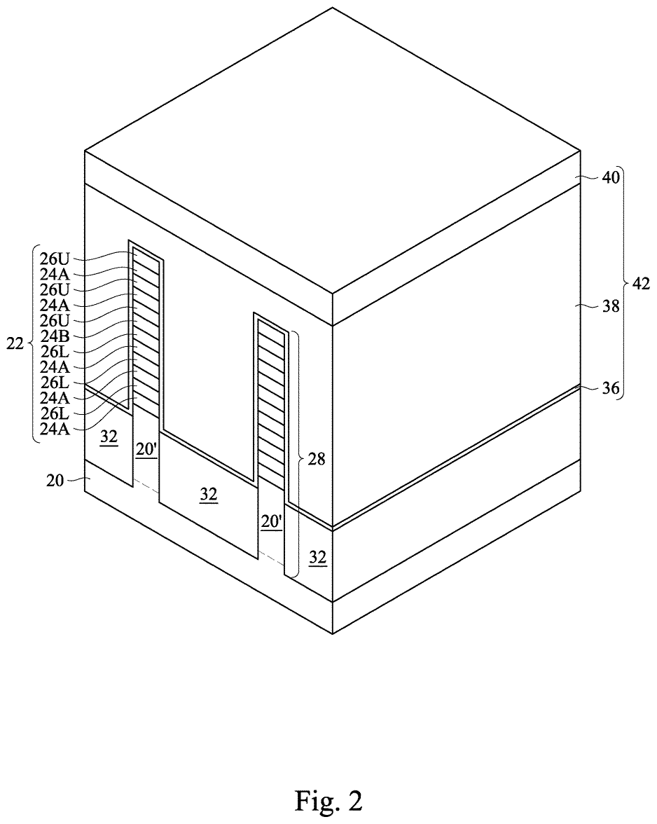

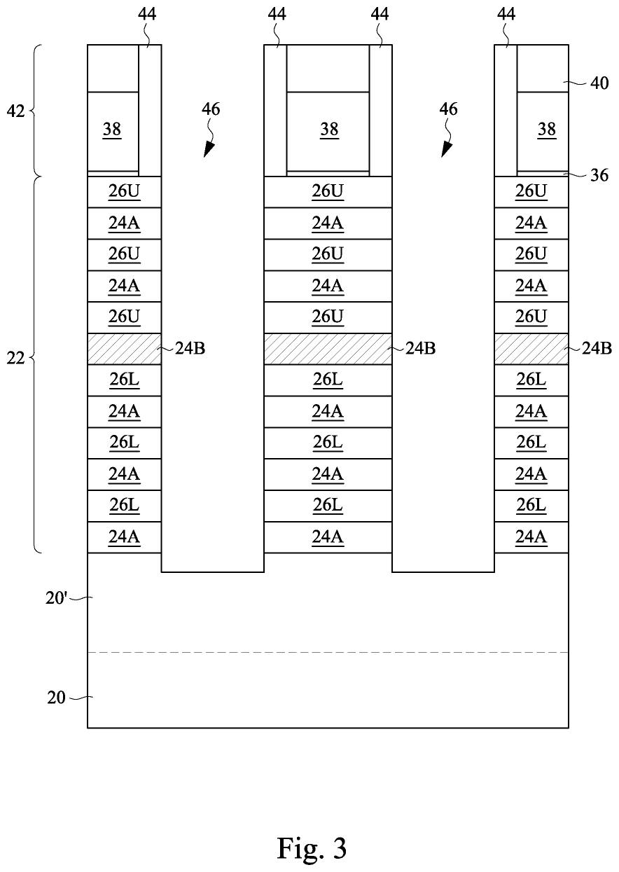

FIGS. 3 through 7 illustrate the cross-sectional views of intermediate stages in the formation of CFETs (as schematically represented in FIG. 1) in accordance with some embodiments. FIGS. 2 through 7 illustrate the vertical cross-sectional views along a similar cross-section as vertical reference cross-section A-A′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20) and multi-layer stack 22. The stacked component of the multi-layers stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24l and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructure 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, dummy semiconductor nanostructures 24A are formed of or comprise silicon germanium, semiconductor layers 26 are formed of silicon, and dummy semiconductor nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures. The isolation structures and the middle semiconductor nanostructures 26M may define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor fins 20′, the dummy nanostructure 24, and the semiconductor nanostructures 26. The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 is formed on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46. FIG. 2 is a cross-sectional view taken along line A-A of FIG. 1. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

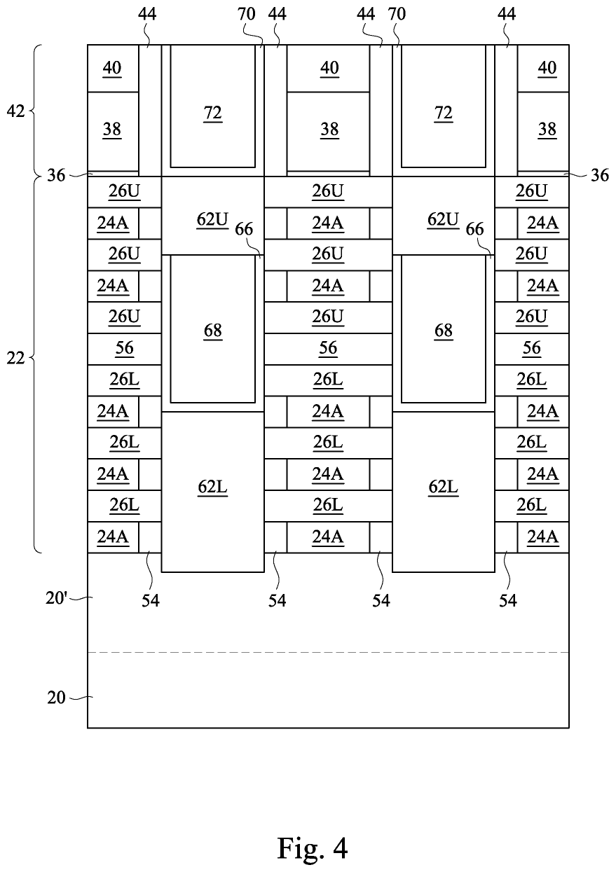

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 56A, and between the upper and lower semiconductor nanostructures 26U and 26L, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26U may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave masks 40 unremoved.

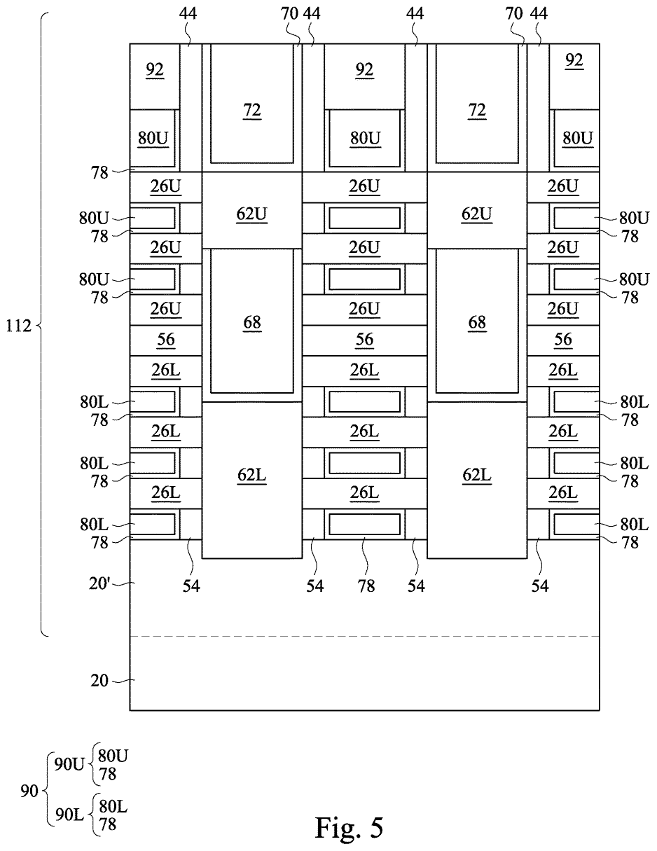

FIG. 5 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 90. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 134L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 134L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As also shown in FIG. 5, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

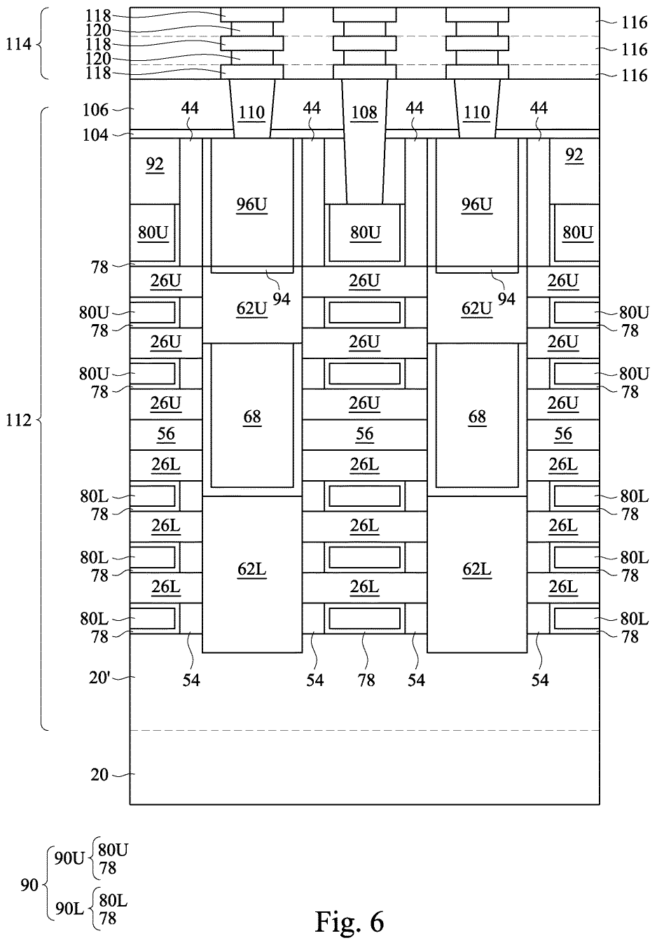

In FIG. 6, silicide regions 94 and source/drain contact plugs 96U are formed through the second ILD 72 to electrically couple to the upper epitaxial source/drain regions 62U and/or the lower epitaxial source/drain regions 62L. An etch stop layer (ESL) 104 and a third ILD 106 are the formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, upper gate contact plugs 108 and source/drain contact plugs 110 are formed to contact the upper gate electrodes 80U and the upper source/drain contact plugs 96U, respectively. The active devices as illustrated are collectively referred to as a device layer 112.

A front-side interconnect structure 114 is formed on the device layer 112. The front-side interconnect structure 114 includes dielectric layers 116 and layers of conductive features 118/120 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118/120 may include conductive lines 118 and vias 120, which may be formed using damascene processes. Conductive features 118/120 may include metal lines 118 and metal vias 120, which includes diffusion barriers and a copper containing material over the diffusion barriers. There may also be aluminum pads over and electrically connected to the metal lines and vias. Depending on how the respective die is to be packaged, the top surface features among the conductive features 118 may include bond pads, metal pillars, solder regions, and/or the like.

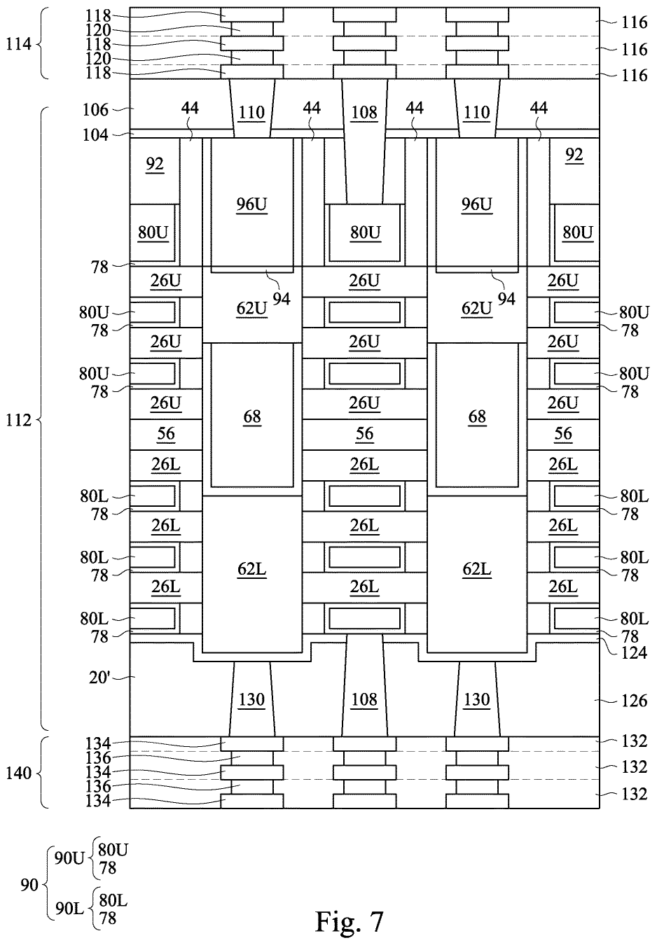

FIG. 7 illustrates a backside interconnect structure 140 in accordance with some embodiments. In some embodiments, electrical connection to the lower gate stacks 90L and the lower source/drain regions 80L may be made through a backside of the device layer 112 (e.g., a side opposite to the front-side interconnect structure 114) with the backside interconnect structure 140. The backside interconnect structure 140 may be similar to the front-side interconnect structure 114 described above the description is not repeated herein. In some embodiments, the connection to the lower gate stacks 90L and the lower source/drain regions 80L be made by contacts (sometimes referred to as contact plugs) and the backside interconnect structure 140 may be omitted.

FIGS. 8A-12C illustrate a formation process of a portion of an interconnect structure with an asymmetrical conductive via in accordance with some embodiments. In this embodiment, the interconnect structure is formed using a dual damascene process. In some embodiments the interconnect structure illustrated in FIGS. 8A-12C is interconnect structures 114 and/or 140.

FIGS. 8A-8B illustrate views of a semiconductor structure at an intermediate stage of processing in the formation of an interconnect structure. FIG. 8A shows a cross-sectional view of the semiconductor structure, while FIG. 8B presents a top-down view of the same structure. The interconnect

The semiconductor structure comprises an underlying structure 150 at the bottom. The underlying structure 150 may be any device or structure that can utilize an interconnect structure. In some embodiments, the underlying structure 150 may include a FinFET, a complementary FET (CFET), a ferroelectric memory FET (FEMFET), or the like. In some embodiments, the underlying structure 150 may be a substrate or the device layer 112 from FIGS. 1-7.

An etch stop layer 154 may be formed on the underlying structure 150. The etch stop layer 154 may be formed of a dielectric material having a high etching selectivity from the etching of an interlayer dielectric 156 and/or the underlying structure 150. In some embodiments, the etch stop layer 154 may comprise silicon nitride, silicon oxide, silicon oxynitride, aluminum oxide, aluminum nitride, or silicon carbon nitride. The etch stop layer 154 may be formed by any suitable deposition process, such as chemical vapor deposition (CVD) or atomic layer deposition (ALD).

An interlayer dielectric 156 may be formed on the etch stop layer 154. The interlayer dielectric 156 may be formed of a dielectric material, which may be deposited by any suitable method, such as CVD, plasma-enhanced CVD (PECVD), or flowable CVD (FCVD). In some embodiments, the interlayer dielectric 156 may include phospho-silicate glass (PSG), boro-silicate glass (BSG), boron-doped phospho-silicate glass (BPSG), undoped silicate glass (USG), or silicon oxide.

A metallization layer 158 may be formed within the interlayer dielectric 156 and the etch stop layer 154 by a damascene process. In some embodiments, the metallization layer 158 is a first metallization layer in the interconnect structure. The metallization layer 158 may include a diffusion barrier layer(s) and a conductive material over the diffusion barrier layer(s). In some embodiments, the conductive material may include copper, a copper alloy, aluminum, the like, or a combination thereof.

Another stack of etch stop layer 160 and interlayer dielectric 162 may be formed over the interlayer dielectric 156 and the metallization layer 158. The etch stop layer 160 and interlayer dielectric 162 may be formed of similar materials and by similar processes as the etch stop layer 154 and interlayer dielectric 156, respectively.

A hardmask 164 may be formed and patterned on the interlayer dielectric 162. The hardmask 164 may include multiple openings that are used to define the subsequently formed trench portions of a metallization layer. In some embodiments, the hardmask 164 may include silicon nitride, silicon oxynitride, boron nitride, silicon carbide, the like, or a combination thereof. In some aspects, a material composition of hardmask layer 164 may be determined to provide a high etch selectivity with an underlying layer, for example with respect to interlayer dielectric 162 and/or etch stop layer 160. The hardmask layer 164 may be formed by PVD, ALD, Plasma-Enhanced Atomic Layer Deposition (PEALD), or the like. Other processes and materials may be used in some embodiments.

In some embodiments, a bilayer masking layer may be utilized. A bilayer masking layer is formed on the film stack over the interlayer dielectric 162 and the hardmask 164. The bilayer masking layer includes a bottom mask layer 166 and a top mask layer 167 over the bottom mask layer 166. The top mask layer 167 may be formed of a photoresist (e.g., a photosensitive material), which includes organic materials, and may be a positive photosensitive material or a negative photosensitive material. The bottom mask layer 166 may be formed of a polymer in some embodiments. The bottom mask layer 166 may also be a bottom anti-reflective coating (BARC) layer. The layers of the bilayer masking layer may be blanket deposited sequentially using, for example, spin-on processes. Other processes and materials may be used.

Although a bilayer masking layer is shown, in other embodiments, a tri-layer or monolayer masking layer may be used instead. For a tri-layer masking layer, a middle layer may be included between the bottom and top layers. The middle layer may include an inorganic material, which may be a nitride (such as silicon nitride), an oxynitride (such as silicon oxynitride), an oxide (such as silicon oxide), or the like. The middle layer may have a high etching selectivity relative to the top layer and the bottom layer. The type of masking layer used (e.g., monolayer masking layer, bilayer masking layer, or tri-layer masking layer) may depend on the photolithography process used to pattern the dielectric layer 162. For example, in some extreme ultraviolet (EUV) lithography processes, a monolayer masking layer or bilayer masking layer may be used.

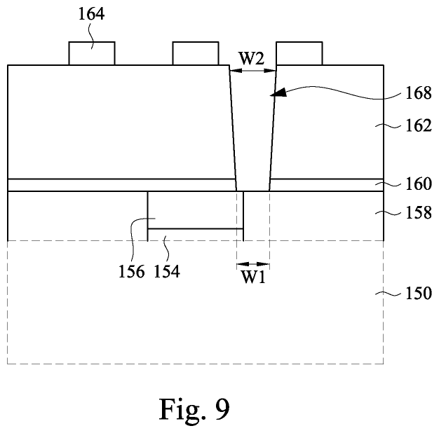

In some embodiments, the top mask layer 167 is patterned using a photolithographic process. Subsequently, the top mask layer 167 is used as an etching mask for patterning of the bottom mask layer 166. The bottom mask layer 166 is then used to pattern the dielectric layer 162 (see FIG. 9). The top mask layer 167 is patterned using any suitable photolithography process to form an opening 168 therein.

As an example of patterning the opening 168 in the top mask layer 167, a photomask (not shown) may be disposed over the top mask layer 167. The top mask layer 167 may then be exposed to a radiation beam including an ultraviolet (UV), an excimer laser, or the like while the photomask masks areas of the top mask layer 167. Exposure of the top photoresist layer may be performed using an immersion lithography system or an extreme ultraviolet lithography system to increase resolution and decrease the minimum achievable critical dimension or pitch. One or multiple exposure steps may be performed. A bake or cure operation may be performed to harden the top mask layer 167, and a developer may be used to remove either the exposed or unexposed portions of the top mask layer 167 depending on whether a positive or negative resist is used. The opening 168 may have a substantially square or rectangular in a plan view (see. e.g., FIG. 8B).

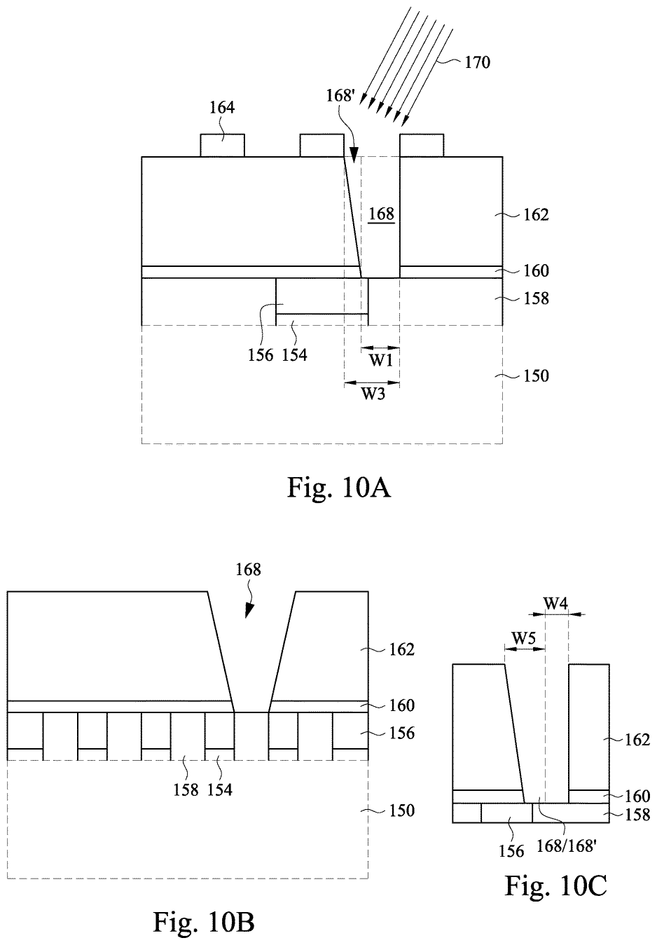

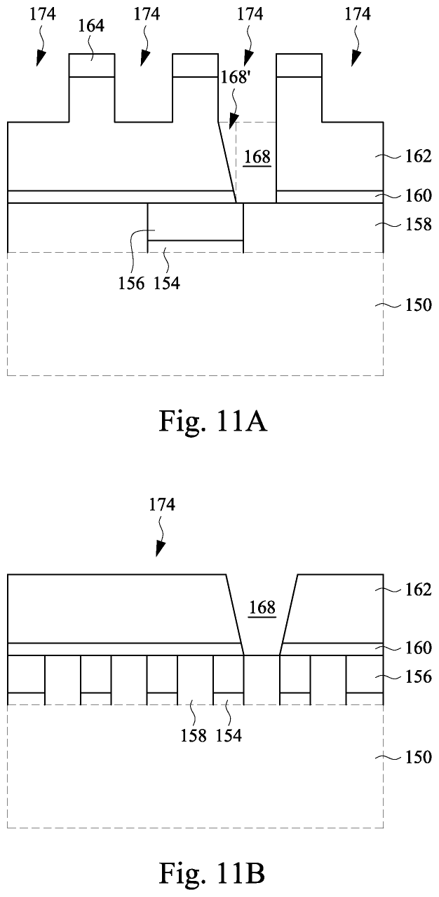

As shown in FIG. 8B, the via opening 168 is positioned to connect with one of the metal lines of the metallization layer 158. The via opening 168 may be substantially square-shaped or rectangular-shaped when viewed from the top-down perspective. The metallization layer 158 is represented by three horizontal bars, indicating multiple metal lines. A reference line labeled D and D′ indicates the plane of the cross-sectional views for FIGS. 8A, 9, 10A, and 11A. A reference line labeled E and E′ indicates the plane of the cross-sectional views for FIGS. 10B and 11B.

FIG. 9 illustrates forming the via opening 168 through the bottom mask layer 166, the interlayer dielectric 162, and the etch stop layer 160 to expose a portion of the metallization layer 158. This may be achieved by an etching process using the top mask layer 167, the bottom mask layer 166, and the hardmask 164 as masks. The etching process of the bottom mask layer 166 and the interlayer dielectric 162 is anisotropic, so that the opening 168 in the top mask layer 167 is extended through the bottom mask layer 166 and the interlayer dielectric 162 and has about the same size (or is slightly smaller) in the bottom mask layer 166 and the interlayer dielectric 162 as it does in the top mask layer 167. As part of etching the interlayer dielectric 162, the top mask layer 167 and the bottom mask layer 166 may be consumed. In some embodiments, portions of the top mask layer and/or bottom mask layer 166 remain, and the top mask layer 167 may be a photoresist and may be removed by an ashing process, and the bottom mask layer 166 may be removed by an etching process.

As shown in FIG. 9, the via opening 168 in the interlayer dielectric 162 may be characterized by two distinct widths. A first width W1 may be measured at the bottom of the via opening 168, near the etch stop layer 160. A second width W2 may be measured at the top of the via opening 168, at the level of the hardmask 164. In some embodiments, the second width W2 may be greater than the first width W1, indicating that the via opening 168 may have a tapered profile, wider at the top than at the bottom.

In some embodiments, the first width W1 at the bottom of the via opening 168 needs to be maintained to preserve a time-dependent dielectric breakdown (TDDB) window. This maintenance of the bottom width can be important for ensuring the reliability and longevity of the interconnect structure. By preserving the TDDB window, the risk of dielectric breakdown over time may be minimized, potentially enhancing the overall performance and lifespan of the semiconductor device.

FIGS. 10A-10C illustrate cross-sectional views of a semiconductor structure undergoing a via formation process with single direction via elongation. FIG. 10A depicts the structure after the elongation process, while FIG. 10B shows the structure along an orthogonal plane to FIG. 10A. FIG. 10C illustrates a detailed view of the enlarged via opening 168/168′.

In FIG. 10A, a directional etching process 170 may be applied to one side of the via opening 168. The directional etching process 170 may create an expanded via opening portion 168′, increasing the width of the via opening 168 on one side. In some embodiments, the directional etching process 170 may be a controllable directional plasma etch process. In some embodiments, the directional etching process 170 may be performed at a power ranging from 100 to 1000 Watts, a bias voltage ranging from 0 to 12,000 volts, a tilt angle ranging from 15 to 60 degrees, and may result in an etch of _0_ to _20_ nanometers on one side of the via opening 168. In some embodiments, the gases used in the etching process include He, Ne, Kr, Ar, CF₄,CHF₃,CH₃F, CH₂F2,C₄F₈, C₄F₆, SF₆ O₂, the like, or a combination thereof.

The directional etching process 170 may enlarge a top portion of the via opening 168 while maintaining the first width W1 at the bottom of the via opening 168. The width of the via opening 168 at the top may increase from the second width W2 to a third width W3. This asymmetrical profile may allow for increased contact area between a subsequently formed via and the metallization layer 158, while maintaining the original width at the bottom of the via opening 168.

In some embodiments, the asymmetry of the via opening 168 may be characterized by a ratio of a width W4 to a width W5 (see, e.g., FIG. 10C). The width W4 may represent the unenlarged side width from a center axis of the via opening 168, while the width W5 may represent the enlarged width side from the center axis of the via opening 168. In some embodiments, the ratio of W5 to W4 may be in a range from 1.2 to 2.5. For example, in a specific embodiment, the width W4 may be 10 nm and the width W5 may range from 12 to 25 nm. The specific ratio values may be adjusted based on the desired contact area and the dimensions of the interconnect structure.

The disclosed ratio of W5 to W4 in the range of 1.2 to 2.5 may provide several advantages for the asymmetrical conductive via structure. This specific range balances competing factors to achieve optimal performance and manufacturability.

At the lower end of the range, a ratio of 1.2 provides a small increase in contact area between the via and the overlying metal layer. This slight asymmetry can be sufficient to reduce contact resistance while minimizing the impact on the surrounding dielectric material.

As the ratio increases towards the upper end of 2.5, the contact area with the overlying metal layer may be significantly increased. This larger contact area can lead to further reductions in contact resistance, improving overall device performance and reducing power consumption. The greater asymmetry also provides more tolerance for alignment variations during the manufacturing process.

However, ratios beyond 2.5 are not be desirable, as they could lead to excessive etching of the dielectric material, potentially compromising the isolation between adjacent structures. Additionally, very large asymmetries can introduce mechanical stress or stability issues in the via structure.

In some cases, the optimal ratio within this range depends on factors such as the specific materials used, the overall dimensions of the device, and the particular performance requirements of the application. The disclosed range provides flexibility for manufacturers to fine-tune the via geometry based on these considerations.

The directional etching process 170 achieves asymmetric via enlargement through precise control of both physical and chemical etching mechanisms. The process employs an anisotropic plasma containing both reactive species and directional ions. In some embodiments, the ion directionality is controlled through a combination of pressure management and bias power application. For example, lower pressure (e.g., in a range from 5-20 mTorr) increases the mean free path of ions, resulting in more vertical ion trajectories, and the bias power (e.g., in a range from 100-500 W) accelerates ions predominantly in the vertical direction.

In some embodiments, the asymmetric profile is achieved by tilting the wafer at a predetermined angle (e.g., in a range from 15-60 degrees) relative to the primary ion direction while maintaining a fixed azimuthal orientation. This tilting, combined with the directional ion bombardment, causes preferential etching on one side of the via opening. The tilt angle directly influences the degree of asymmetry, with larger angles producing greater differential etching between the enlarged and unenlarged sides.

For example, some parameters that influence the final asymmetric profile include: the tilt angle of the wafer relative to the ion direction; the duty cycle of bias power modulation; the total etch time; and the gas chemistry composition and flow rates.

The directionality of the etching process is maintained until the desired asymmetric profile is achieved. In some embodiments, the directional etching process 170 may be controlled such that the ions move along the direction of the etch. This control may allow for precise enlargement of the via opening 168 on one side, creating the expanded via opening portion 168′.

FIG. 10B shows the structure along an orthogonal plane to FIG. 10A. In this view, the via opening 168 may appear symmetrical, as the via opening 168 in this cross-section may be substantially unaffected by the directional etching process 170. The asymmetrical via opening profile is characterized by having an asymmetrical shape with the enlarged top portion on one side when viewed in a first cross-sectional direction, while showing a symmetrical shape when viewed in a second cross-sectional direction perpendicular to the first direction

The single direction via elongation technique may offer several benefits. The asymmetrical profile created by the directional etching process 170 may help reduce contact resistance while preserving the critical dimensions of the lower metallization layer 158 and the integrity of the surrounding interlayer dielectric 162. Additionally, maintaining the first width W1 at the bottom of the via opening 168 can be important for preserving a time-dependent dielectric breakdown (TDDB) window.

FIGS. 11A and 11B illustrate cross-sectional views of the semiconductor structure after trench openings 174 are formed over the enlarged via opening including the via opening 168 and the expanded via opening portion 168′. The trench openings 174 may be formed in the hardmask 164 and the interlayer dielectric 162.

In some embodiments, the trench openings 174 may be formed by an etching process, such as an anisotropic etching process. The etching process may use the hardmask 164 as a mask to define the locations for the trench openings 174 in the interlayer dielectric 162. The etching process may be selective to the interlayer dielectric 162, allowing for controlled formation of the trench openings 174 without significantly affecting the underlying layers.

The trench openings 174 may be spatially connected with the via opening 168. This spatial connection may create a continuous opening from the trench openings 174 through the via opening 168 to the underlying metallization layer 158. The continuous opening may facilitate the subsequent formation of a conductive structure that electrically connects multiple layers of the semiconductor device.

The formation of the trench openings 174 with the via opening 168 may be part of a dual damascene process. In this process, both the via opening 168 and the trench openings 174 may be filled with conductive material in a single step, simplifying the manufacturing process and improving the electrical characteristics of the resulting interconnect structure.

As seen in FIG. 11A, the via opening 168 may still maintain the asymmetric profile created by the directional etching process 170, with an enlarged left side corresponding to the expanded via opening portion 168′. This asymmetric profile may be preserved during the formation of the trench openings 174, allowing for increased contact area with subsequently formed conductive structures while maintaining the first width W1 at the bottom of the via opening 168.

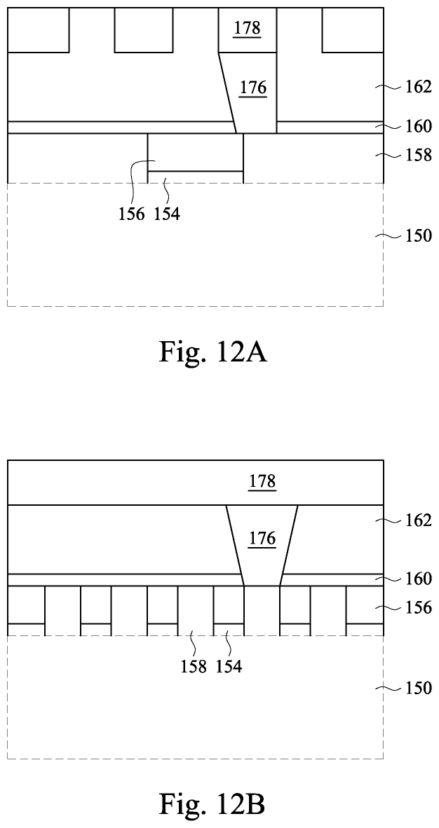

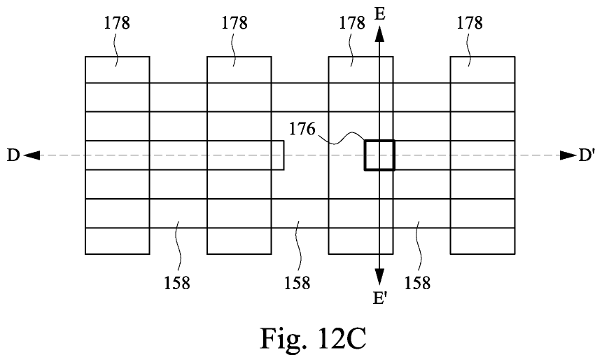

FIGS. 12A-12C illustrate forming a conductive material in the via opening 168/168′ and the trench opening 174 to form an asymmetrical conductive via 176 and a metallization layer 178.

In some embodiments, the formation of the conductive material in the via opening 168/168′ and the trench opening 174 may involve a multi-step process. A liner layer may be deposited on the sidewalls and bottom of the via opening 168/168′ and the trench opening 174. The liner layer may serve as a diffusion barrier layer, an adhesion layer, or both. In some embodiments, the liner layer may include titanium, titanium nitride, tantalum, tantalum nitride, the like, or a combination thereof.

After the liner layer deposition, a bulk conductive material may be deposited to fill the remaining space in the via opening 168/168′ and the trench opening 174. The bulk conductive material may be cobalt, tungsten, copper, a copper alloy, silver, gold, aluminum, nickel, ruthenium, the like, or a combination thereof. In some embodiments, the bulk conductive material may be deposited using techniques such as electroplating, CVD, PVD, or the like.

After forming the bulk conductive material, a removal process may be performed to remove excess material from the top surfaces of the interlayer dielectric 162. In some embodiments, the removal process may be a planarization process such as chemical mechanical polishing (CMP), an etch-back process, or a combination thereof. The removal process may also remove any remaining hardmask 164. After the planarization process, the top surfaces of the metallization layer 178 and the interlayer dielectric 162 may be substantially coplanar, within process variations. The remaining liner layer and bulk conductive material may form the asymmetrical conductive via 176 and the metallization layer 178 in the openings.

FIG. 12C provides a top-down view of the semiconductor structure. Two dashed lines labeled D-D′ and E-E′ indicate the planes of the cross-sectional views shown in FIGS. 12A and 12B, respectively. FIG. 12C illustrates the layout of the metallization layer 158, the metallization layer 178, and the asymmetrical conductive via 176. The metallization layer 158 is represented by horizontal bars, while the metallization layer 178 is shown as vertical bars.

The asymmetrical conductive via 176 electrically connect one of the metallization layers 158 to one of the metallization layers 178. This connection may create electrical pathways between different layers of the semiconductor device. The asymmetrical shape of the asymmetrical conductive via 176 may allow for increased contact area with the metallization layer 178 while maintaining the bottom critical dimension where the asymmetrical conductive via 176 contacts the metallization layer 158.

In some embodiments, the asymmetrical conductive via 176 may be positioned at different locations relative to the metallization layers 158 and 178. In some embodiments, the asymmetrical conductive via 176 is positioned at a line-end of the metallization layer 158, where the enlarged portion of the asymmetrical conductive via 176 extends beyond the line-end to increase the contact area while maintaining the critical bottom width. In other embodiments, the asymmetrical conductive via 176 is positioned on a sidewall of the metallization layer 178, where the asymmetrical profile with its enlarged portion provides increased contact area with the sidewall of the metallization layer 178. These positioning configurations are particularly advantageous in advanced layout scenarios where traditional symmetric vias would provide insufficient contact area due to the reduced overlap between the via and the metallization layers. The single direction via elongation in these positions enables reliable electrical connections while maintaining compatibility with layout push techniques such as enclosure reduction and cut metallization layer removal.

While FIGS. 8A-12C illustrate only one asymmetrical conductive via 176, the disclosure may contemplate more vias. Similarly, the number of metallization layers 158 and 178 may vary from the number shown in the figures. In some embodiments, there may be multiple asymmetrical conductive vias 176 connecting various portions of the metallization layers 158 and 178. Additionally, this via configuration may be applied to other layers of the interconnect structure above or below the illustrated layers, allowing for flexibility in the overall interconnect design and potentially enhancing the performance of the semiconductor device at various levels.

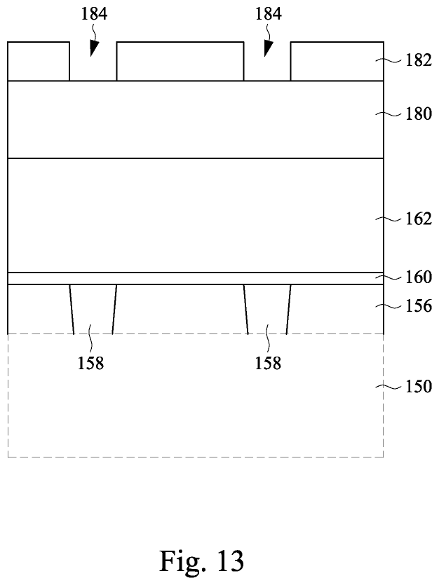

FIGS. 13-17 illustrate cross-sectional views of a formation process of a portion of an interconnect structure with an asymmetrical conductive via in accordance with some embodiments. In this embodiment, the interconnect structure may be formed using a single damascene process. In some embodiments the interconnect structure illustrated in FIGS. 13-16 is the interconnect structure 114 and/or 140.

FIG. 13 illustrates a similar stage of processing as FIGS. 8A and 8B described above. However, in this embodiment, a bottom mask layer 180 and a top mask layer 182 may be formed over the interlayer dielectric 162.

The mask layers 180 and 182 may be similar to the mask layers 166 and 167 described above, and the description is not repeated herein. In some embodiments, they can be a tri-layer mask layer set as described above. In some embodiments, the bottom mask layer 180 includes a dielectric material such as tetraethyl orthosilicate (TEOS), while the top mask layer 182 may comprise a photoresist. In some embodiments, the top mask layer 182 may be a multi-film stack such as photoresist/middle layer/bottom layer stack. This configuration may provide enhanced control and precision during the patterning and etching processes used to form the via and trench structures.

The via openings 184 may be formed similarly to the via opening 168 described above in FIGS. 8A and 8B and the description is not repeated herein. In contrast to the dual damascene process described earlier, the single damascene process may involve forming and filling the via openings and trench openings in separate steps. This approach may offer greater flexibility in optimizing the formation of each structure independently.

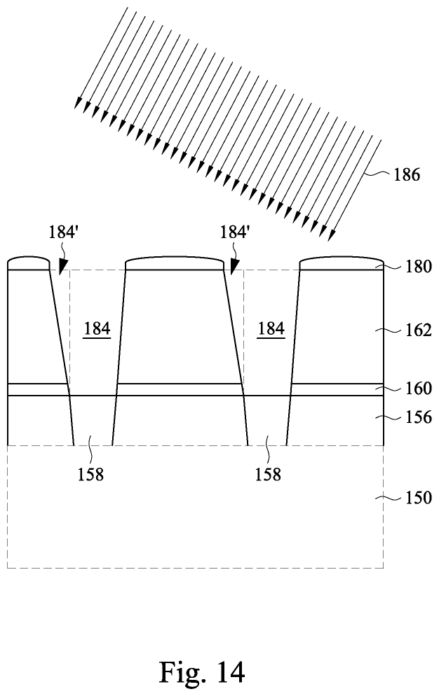

FIG. 14 illustrates extending the via openings 184 through the bottom mask layer 180, the interlayer dielectric 162, and the etch stop layer 160 to expose the metallization layer 158.

In some embodiments, the via openings 184 may be extended using an etching process, such as an anisotropic etching process. The details of extending the via opening may be similar to that described above in FIG. 9 and the description is not repeated herein.

A directional etching process 186 may be applied to enlarge one side of each via opening 184. The directional etching process 186 may be similar to the directional etching process 170 described above and the description is not repeated herein. The directional etching process 186 may create an enlarged via opening portion 184′ at the top of each via opening 184. In some embodiments, the directional etching process 186 may be a controllable directional plasma etch process.

The directional etching process 186 may enlarge a top portion of the via openings 184 while maintaining a first width at the bottom of the via openings 184. The width of the via openings 184 at the top may increase from a second width to a third width. This asymmetrical profile may allow for increased contact area with subsequently formed conductive structures while maintaining the first width at the bottom of the via openings 184.

In some embodiments, the directional etching process 186 may be controlled such that the ions move along the direction of the etch. This control may allow for precise enlargement of the via openings 184 on one side, creating the enlarged via opening portions 184′.

In some embodiments, maintaining the first width at the bottom of the via openings 184 may be important for preserving a time-dependent dielectric breakdown (TDDB) window. The asymmetrical profile created by the directional etching process 186 may help reduce contact resistance while preserving the critical dimensions of the metallization layer 158 and the integrity of the surrounding interlayer dielectric 162.

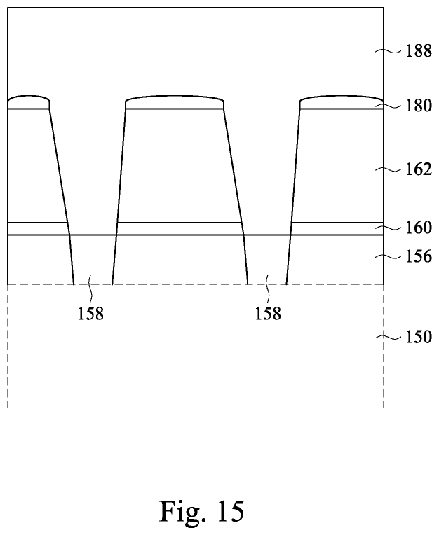

FIG. 15 illustrates the formation of a conductive material 188 in the via openings 184/184′ and over the interlayer dielectric 162 and the bottom mask layer 180 (if still present). In some embodiments, the formation of the conductive material 188 in the via openings 184/184′ may involve a multi-step process. A liner layer may be deposited on the sidewalls and bottom of the via openings 184/184′. The liner layer may serve as a diffusion barrier layer, an adhesion layer, or both. In some embodiments, the liner layer may include titanium, titanium nitride, tantalum, tantalum nitride, or a combination thereof.

After the liner layer deposition, a bulk conductive material may be deposited to fill the remaining space in the via openings 184/184′. The bulk conductive material may be cobalt, tungsten, copper, a copper alloy, silver, gold, aluminum, nickel, ruthenium, or a combination thereof. In some embodiments, the bulk conductive material may be deposited using techniques such as electroplating, CVD, PVD, or the like.

The conductive material 188 may extend over the interlayer dielectric 162 and the bottom mask layer 180 (if still present). In some embodiments, the conductive material 188 may form electrical connections between the upper layers of the structure and the metallization layers 158. The asymmetrical profile of the via openings 184/184′, created by the directional etching process 186, may allow for increased contact area with the upper layers while maintaining the first width at the bottom of the via openings 184/184′.

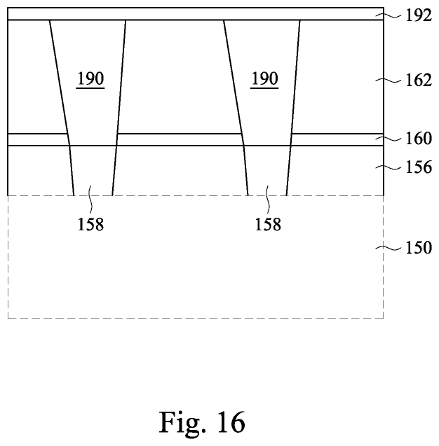

FIG. 16 illustrates the formation of asymmetrical conductive vias 190 and an etch stop layer 192. After the formation of the conductive material 188 in the via openings 184/184′, a removal process may be performed to remove excess material from the top surfaces of the interlayer dielectric 162. In some embodiments, the removal process may be a planarization process such as CMP, an etch-back process, or a combination thereof. The removal process may remove remaining portions of the bottom mask layer 180. After the planarization process, the top surfaces of the asymmetrical conductive vias 190 and the interlayer dielectric 162 may be substantially coplanar (within process variations).

The asymmetrical conductive vias 190 may extend through the interlayer dielectric 162 and the etch stop layer 160, contacting the metallization layer 158 below. In some embodiments, the asymmetrical conductive vias 190 may have an asymmetrical shape, with a wider upper portion and a narrower lower portion. The wider upper portion may correspond to the enlarged via opening portion 184′ created by the directional etching process 186.

Further illustrated in FIG. 16, an etch stop layer 192 is formed over the interlayer dielectric 162 and the asymmetrical conductive vias 190. In some embodiments, the etch stop layer 192 may comprise similar materials and be formed by similar processes as the etch stop layer 160. The etch stop layer 192 may serve as a stopping point for subsequent etching processes and may help protect the underlying layers during these processes.

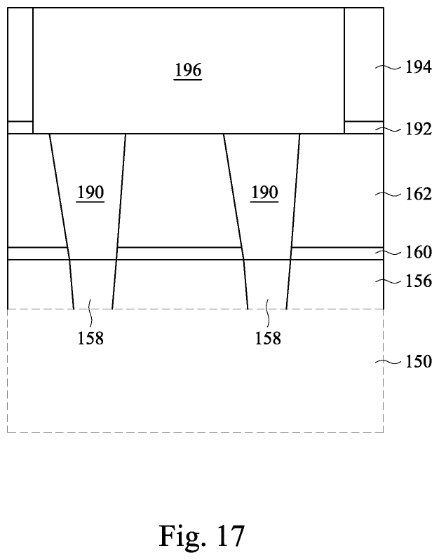

FIG. 17 illustrates the formation of an interlayer dielectric 194 and a metallization layer 196 in the interlayer dielectric 194. In some embodiments, the interlayer dielectric 194 may be formed over the etch stop layer 192 and the asymmetrical conductive vias 190. The interlayer dielectric 194 may be similar to the interlayer dielectric 162 in composition and formation process.

The metallization layer 196 may be formed to extend through the interlayer dielectric 194 and the etch stop layer 192 to make electrical contact with the asymmetrical conductive vias 190 below. In some embodiments, the metallization layer 196 may be formed of a similar conductive material as the asymmetrical conductive vias 190. The formation of the metallization layer 196 may involve similar processes as those used for forming the asymmetrical conductive vias 190, such as depositing a liner layer followed by filling with a bulk conductive material.

In some embodiments, the metallization layer 196 may be electrically connected to multiple asymmetrical conductive vias 190. This arrangement may create electrical pathways from the lower metallization layer 158 through the asymmetrical conductive vias 190 to the upper metallization layer 196.

The asymmetrical shape of the asymmetrical conductive vias 190 may allow for increased contact area with the metallization layer 196 while maintaining a smaller contact area with the metallization layer 158. In some embodiments, this configuration may potentially reduce contact resistance in the upper portion while preserving the integrity of the lower metallization layer 158.

After the formation of the metallization layer 196, a planarization process may be performed to remove excess material from the top surface of the interlayer dielectric 194. In some embodiments, the planarization process may be a CMP process, an etch-back process, or a combination thereof. After the planarization process, the top surfaces of the metallization layer 196 and the interlayer dielectric 194 may be substantially coplanar (within process variations).

The completion of these steps may complete the single damascene process for forming this layer of the interconnect structure. The resulting structure may include the asymmetrical conductive vias 190 with their unique profile created by the directional etching process 186, providing potential benefits in terms of reduced contact resistance and maintained reliability.

While FIGS. 13-17 illustrate only two asymmetrical conductive vias 190, the disclosure may contemplate more or fewer vias. Similarly, the number of metallization layers 158 and 196 may vary from the number shown in the figures. In some embodiments, there may be multiple asymmetrical conductive vias 190 connecting various portions of the metallization layers 158 and 196. Additionally, this via configuration may be applied to other layers of the interconnect structure above or below the illustrated layers, allowing for flexibility in the overall interconnect design and potentially enhancing the performance of the semiconductor device at various levels.

By utilizing the single direction via elongation technique described herein, issues in advanced semiconductor manufacturing are addressed, particularly high contact resistance and limited process windows. The disclosed process balances the need for increased contact area with the requirement to maintain critical dimensions for reliability.

The method involves forming a via hole in a dielectric layer, performing a directional etching to enlarge one side of the via hole, and then forming a trench hole above and spatially connected with the via hole. The via hole and trench hole are then filled with a conductive material. This process may be applied in both dual damascene and single damascene techniques. This unique profile allows for increased contact area with the overlying metal layer while maintaining the critical bottom dimensions.

This disclosed embodiments to via formation may offer several benefits. The increased contact area between the via and the overlying metal layer helps reduce contact resistance. At the same time, maintaining the original bottom width of the via helps preserve the time-dependent dielectric breakdown (TDDB) window between the via and adjacent portions of the underlying metal layer. This balance between increased contact area and maintained bottom width improves performance while helping to ensure reliability.

Additionally, the single direction via elongation technique improves the via contact window, providing greater tolerance for overlay variations. This increased process window can lead to improved manufacturing yield, especially in advanced technology nodes where precise alignment becomes increasingly challenging. The approach is also be compatible with layout push techniques for continued density and performance enhancement. Overall, this method may enhance device performance, reduce power consumption, and improve manufacturing yield through increased process windows.

In an embodiment, a method may include forming a via hole in a dielectric layer, performing a directional etching process to enlarge one side of the via hole, and after the directional etching process, forming a trench hole in the dielectric layer, where the trench hole is above and spatially connected with the via hole, where the directional etching creates an asymmetrical profile having a first side width and a second side width measured from a center of the via hole, the second side width being greater than the first side width. The method may further include filling the via hole and the trench hole with a conductive material.

The described embodiments may also include one or more of the following features. The method where the directional etching enlarges a top portion of the via hole and does not change a bottom width of the via hole. The method where after the direction etching process, the via hole in a cross-sectional profile along a first direction has an asymmetrical shape with the enlarged top portion on one side, and the via hole in a cross-sectional profile along a second direction perpendicular to the first direction has a symmetrical shape. The method may include forming a hardmask layer on the dielectric layer before forming the via hole, and patterning the hardmask layer to define a location for the trench hole. The method where forming the via hole may include forming a bottom mask layer on the hardmask layer, forming a top mask layer on the bottom mask layer, and patterning the top mask layer to define a location for the via hole. The method may include removing the top mask layer and the bottom mask layer after performing the directional etching. The method where the dielectric layer is formed over a complementary field-effect transistor (CFET) structure having a lower nanostructure-FET and an upper nanostructure-FET, and where the conductive material is electrically coupled to at least one of the lower nanostructure-FET or the upper nanostructure-FET.

In an embodiment, a semiconductor device may include a first metallization layer, a dielectric layer over the first metallization layer, and an asymmetrical conductive via in the dielectric layer, the asymmetrical conductive via having a first width at a bottom portion contacting the first metallization layer and a second width at a top portion, where the top portion has a first side width and a second side width measured from a center of the asymmetrical conductive via, the second side width being greater than the first side width.

The described embodiments may also include one or more of the following features. The semiconductor device may include a second metallization layer over the dielectric layer, where the asymmetrical conductive via electrically connects the first metallization layer to the second metallization layer. The semiconductor device where the asymmetrical conductive via is positioned on a sidewall of the second metallization layer. The semiconductor device where a ratio of the first side width to the second side width is in a range from 1.2 to 2.5. The semiconductor device may include a complementary field-effect transistor (CFET) structure having a lower nanostructure-FET and an upper nanostructure-FET, where the first metallization layer is formed over the CFET structure, and where the asymmetrical conductive via is electrically coupled to at least one of the lower nanostructure-FET or the upper nanostructure-FET. The semiconductor device where the asymmetrical conductive via may include an enlarged portion extending in a single direction relative to a center axis of the asymmetrical conductive via. The semiconductor device where the asymmetrical conductive via is positioned at a line-end of the first metallization layer.

In an embodiment, a method may include forming a complementary field-effect transistor (CFET) structure having a lower nanostructure-FET and an upper nanostructure-FET, forming a via opening in a dielectric layer over the CFET structure, performing a directional etching process to enlarge a top portion of the via opening on one side of the via opening, and filling the via opening with a conductive material to form an asymmetrical conductive via.

The described embodiments may also include one or more of the following features. The method where the directional etching process may include a controllable directional plasma etch process. The method may include forming a hardmask layer on the dielectric layer before forming the via opening, and patterning the hardmask layer to define a location for a trench opening. The method may include forming the trench opening in the dielectric layer after performing the directional etching process, where the trench opening is above and spatially connected with the via opening. The method where after filling the via opening and the trench opening with the conductive material, the asymmetrical conductive via in a cross-sectional profile along a first direction has an asymmetrical shape with the enlarged top portion on one side, and the asymmetrical conductive via in a cross-sectional profile along a second direction perpendicular to the first direction has a symmetrical shape. The method where the directional etching process creates an asymmetrical profile having a ratio of an enlarged side width to an unenlarged side width of in a range from 1.2 to 2.5 measured from a center of the via opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first metallization layer;
a dielectric layer over the first metallization layer; and
an asymmetrical conductive via in the dielectric layer and contacting the first metallization layer, the asymmetrical conductive via comprising an enlarged portion at a top portion of the asymmetrical conductive via on one side of the asymmetrical conductive via,
wherein the asymmetrical conductive via has an asymmetrical shape with the enlarged portion on the one side in a first cross-section and has a symmetrical shape in a second cross-section perpendicular to the first cross-section, and
wherein the dielectric layer is in contact with a sidewall of the enlarged portion.

2. The semiconductor device of claim 1, further comprising a second metallization layer over the dielectric layer, wherein the asymmetrical conductive via electrically connects the first metallization layer to the second metallization layer.

3. The semiconductor device of claim 2, wherein the asymmetrical conductive via is on a sidewall of the second metallization layer.

4. The semiconductor device of claim 1, wherein the asymmetrical conductive via has a first width at a bottom portion contacting the first metallization layer and a second width at the top portion, the second width being greater than the first width.

5. The semiconductor device of claim 1, wherein the top portion has a first side width and a second side width measured from a center of the asymmetrical conductive via, the second side width being greater than the first side width.

6. The semiconductor device of claim 5, wherein a ratio of the second side width to the first side width is in a range from 1.2 to 2.5.

7. The semiconductor device of claim 1, wherein the asymmetrical conductive via is at a line-end of the first metallization layer, and the enlarged portion extends beyond the line-end.

8. A method, comprising:
forming a via opening in a dielectric layer over a metallization layer, the via opening exposing the metallization layer;
performing a directional plasma etch process to enlarge a top portion of the via opening on one side of the via opening while maintaining a first width at a bottom of the via opening, wherein the directional plasma etch process comprises tilting a wafer at an angle relative to a primary ion direction of the directional plasma etch process while maintaining a fixed azimuthal orientation of the wafer, such that the via opening has an asymmetrical shape with the enlarged top portion on the one side in a first cross-section and has a symmetrical shape in a second cross-section perpendicular to the first cross-section; and
filling the via opening with a conductive material to form an asymmetrical conductive via.

9. The method of claim 8, further comprising forming a hardmask layer on the dielectric layer before forming the via opening, and patterning the hardmask layer to define a location for a trench opening.

10. The method of claim 9, further comprising forming the trench opening in the dielectric layer after performing the directional plasma etch process, wherein the trench opening is above and spatially connected with the via opening, and wherein the conductive material fills the via opening and the trench opening.

11. The method of claim 8, wherein forming the via opening comprises forming a bottom mask layer over the dielectric layer, forming a top mask layer on the bottom mask layer, and patterning the top mask layer to define a location for the via opening.

12. The method of claim 8, wherein the directional plasma etch process creates an asymmetrical profile having a ratio of an enlarged side width to an unenlarged side width, measured from a center of the via opening, in a range from 1.2 to 2.5.

13. The method of claim 8, wherein the dielectric layer is over a complementary field-effect transistor (CFET) structure comprising a lower nanostructure-FET and an upper nanostructure-FET, and the conductive material is electrically coupled to the lower nanostructure-FET or the upper nanostructure-FET.

14. The method of claim 8, further comprising, after filling the via opening, forming an etch stop layer over the asymmetrical conductive via and forming a second metallization layer contacting the asymmetrical conductive via, wherein the via opening and the second metallization layer are filled in separate steps.

15. A semiconductor device, comprising:
a complementary field-effect transistor (CFET) structure comprising a lower nanostructure-FET and an upper nanostructure-FET;
a first metallization layer over the CFET structure;
a dielectric layer over the first metallization layer; and
an asymmetrical conductive via in the dielectric layer, contacting the first metallization layer, and electrically coupled to the lower nanostructure-FET or the upper nanostructure-FET, the asymmetrical conductive via comprising an enlarged portion at a top portion of the asymmetrical conductive via on one side of the asymmetrical conductive via,
wherein the asymmetrical conductive via has an asymmetrical shape with the enlarged portion on the one side in a first cross-section and has a symmetrical shape in a second cross-section perpendicular to the first cross-section.

16. The semiconductor device of claim 15, further comprising a second metallization layer over the dielectric layer, wherein the asymmetrical conductive via electrically connects the first metallization layer to the second metallization layer.

17. The semiconductor device of claim 15, wherein the asymmetrical conductive via has a first width at a bottom portion contacting the first metallization layer and a second width at the top portion, the second width being greater than the first width.

18. The semiconductor device of claim 15, further comprising a dielectric isolation layer between the lower nanostructure-FET and the upper nanostructure-FET.

19. The semiconductor device of claim 15, wherein the lower nanostructure-FET comprises lower semiconductor nanostructures and the upper nanostructure-FET comprises upper semiconductor nanostructures, and gate dielectrics encircle the respective lower and upper semiconductor nanostructures.

20. The semiconductor device of claim 15, wherein the asymmetrical conductive via is at a line-end of the first metallization layer, and the enlarged portion extends beyond the line-end.
